(19) United States
(12) Patent Application Publication
(10) Pub. No.: US 2026/0248024 A1
(43) Pub. Date: Aug. 20, 2026

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Dohyun KIM, Suwon-si (KR); Eunah KO, Suwon-si (KR); Yuna KIM, Suwon-si (KR); Jongyong KIM, Suwon-si (KR); Hyoeun KIM, Suwon-si (KR)

(73) Assignee: SAMSUNG ELECTRONICS CO., LTD., Suwon-si (KR)

(21) Appl. No.: 19/344,930

(22) Filed: Sep. 30, 2025

(30) Foreign Application Priority Data
Feb. 17, 2025 (KR) 10-2025-0020375

(51) Int. Cl. H01L 23/31; H01L 23/00; H01L 23/498; H01L 25/18; H10B 80/00; H10D 80/30

(52) U.S. Cl. CPC H10W 74/111; H10B 80/00; H10D 80/30; H10W 90/00; H10W 74/15; H10W 90/401; H10W 90/724; H10W 90/734

(57) ABSTRACT

Provided are a semiconductor package having a structure in which semiconductor devices are stacked on an interposer to reduce thermal stress, increase an adhesive force of an underfill, and reduce the size of the package, and a method of manufacturing the semiconductor package. The semiconductor package includes a package substrate, an interposer disposed on the package substrate and connected to the package substrate through a first connection terminal and a first underfill, a first semiconductor device disposed on the interposer and connected to the interposer through a second connection terminal and a second underfill, and a sealing material disposed on the interposer and sealing a first semiconductor device. A part of a side surface of the second underfill is exposed from a side surface of the sealing material.

### CROSS-REFERENCE TO RELATED APPLICATION

This application is based on and claims priority under 35 U.S.C. § 119 to Korean Patent Application No. 10-2025-0020375, filed on Feb. 17, 2025, in the Korean Intellectual Property Office, the disclosure of which is incorporated by reference herein in its entirety.

### BACKGROUND

The inventive concept relates to a semiconductor package, and more particularly, to a semiconductor package including an interposer and a method of manufacturing the semiconductor package.

With the rapid development of the electronics industry and user demands, electronic devices are becoming smaller and lighter. As electronic devices become smaller and lighter, semiconductor packages used in the electronic devices are also becoming smaller and lighter, and semiconductor packages are required to have high reliability along with high performance and large capacity. In order to realize miniaturization, light weight, high performance, large capacity, and high reliability, research and development on semiconductor packages having a structure in which semiconductor chips are stacked by using an interposer are continuously conducted.

### SUMMARY

The inventive concept provides a semiconductor package having a structure in which semiconductor devices are stacked on an interposer to reduce thermal stress, increase an adhesive force of an underfill, and reduce the size of the package, and a method of manufacturing the semiconductor package.

Technical problems to be solved by the inventive concept are not limited to the above-described technical problems and one of ordinary skill in the art will understand other technical problems from the following description.

According to an aspect of the inventive concept, a semiconductor package includes a package substrate, an interposer disposed on the package substrate and connected to the package substrate through a first connection terminal and a first underfill, a first semiconductor device disposed on the interposer and connected to the package interposer through a second connection terminal and a second underfill, and a sealing material disposed on the interposer and sealing a first semiconductor device. A part of a side surface of the second underfill is exposed from a side surface of the sealing material.

According to another aspect of the inventive concept, a semiconductor package includes a package substrate, an interposer disposed on the package substrate and connected to the package substrate through a first connection terminal, a first semiconductor device disposed on the interposer and connected to the interposer through a second connection terminal, a first underfill disposed between the package substrate and the interposer and covering the first connection terminal, a second underfill disposed between the interposer and the first semiconductor device and covering the second connection terminal, and a sealing material disposed on the interposer and sealing a first semiconductor device. The second underfill covers at least a part of a side surface of the first semiconductor device, a first side surface of the second underfill is exposed from a side surface of the sealing material, and the first underfill covers a side surface of the interposer and at least a part of the first side surface of the second underfill.

According to another aspect of the inventive concept, a semiconductor package includes a package substrate, an interposer disposed on the package substrate and connected to the package substrate through a first connection terminal and a first underfill, a first semiconductor device disposed on the interposer and connected to the interposer through a second connection terminal and a second underfill, a second semiconductor device disposed adjacent to the first semiconductor device on the interposer and connected to the interposer through a third connection terminal and a third underfill, and a sealing material disposed on the interposer and sealing a first semiconductor device and the second semiconductor device. A first side surface of the second underfill is exposed from a side surface of the sealing material.

### BRIEF DESCRIPTION OF THE DRAWINGS

Embodiments will be more clearly understood from the following detailed description taken in conjunction with the accompanying drawings in which:

FIG. 1 is a cross-sectional view illustrating a semiconductor package, according to an embodiment;

FIGS. 2A and 2B are enlarged views illustrating a portion A of FIG. 1;

FIG. 3 is a cross-sectional view illustrating a comparison between sizes of the semiconductor package of FIG. 1 and a semiconductor package of a comparative example;

FIGS. 4A and 4B are cross-sectional views illustrating a semiconductor package, according to embodiments;

FIG. 5 is a cross-sectional view illustrating a semiconductor package, according to an embodiment;

FIGS. 6A to 6C are detailed cross-sectional views illustrating a structure of a second semiconductor device in the semiconductor package of FIG. 5;

FIGS. 7A and 7B are a perspective view and a cross-sectional view illustrating a semiconductor package, according to an embodiment;

FIGS. 8A to 8F are cross-sectional views schematically illustrating processes of a method of manufacturing a semiconductor package, according to an embodiment; and

FIGS. 9A to 9C are cross-sectional views schematically illustrating processes of a method of manufacturing a semiconductor package, according to an embodiment.

### DETAILED DESCRIPTION OF THE EMBODIMENTS

Hereinafter, embodiments will be described in detail with reference to the accompanying drawings. The same components in the drawings are denoted by the same reference numerals, and a repeated description thereof will be omitted.

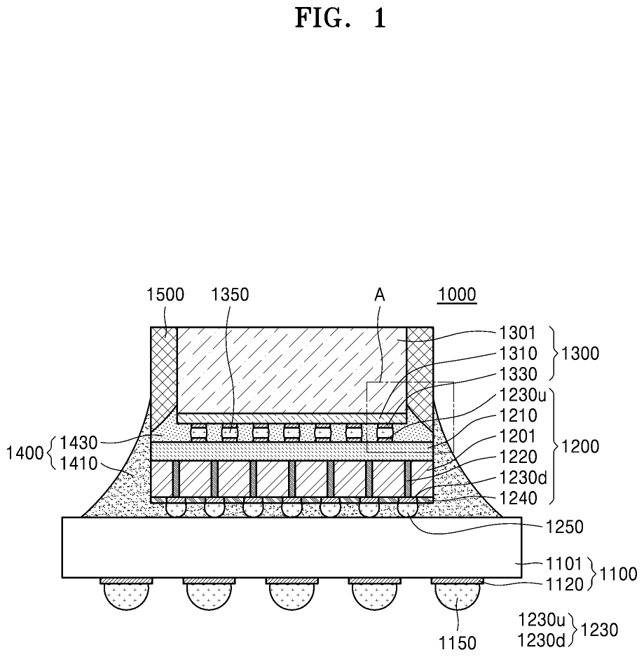

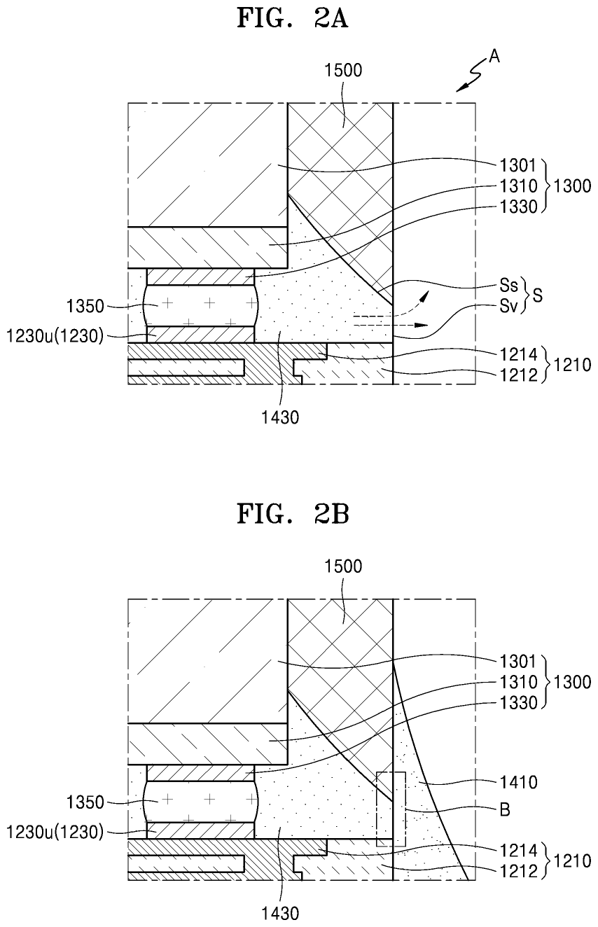

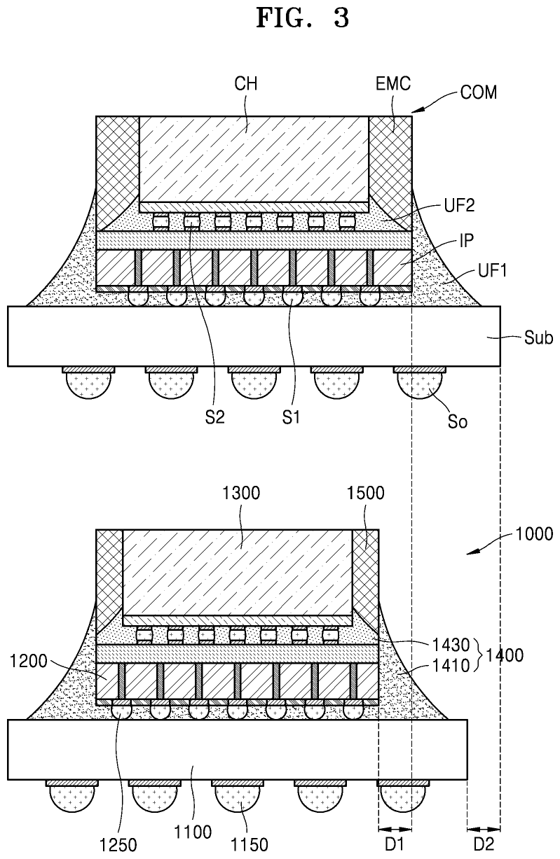

FIG. 1 is a cross-sectional view illustrating a semiconductor package, according to an embodiment. FIGS. 2A and 2B are enlarged views illustrating a portion A of FIG. 1. FIG. 2A is a cross-sectional view before a first underfill is formed. FIG. 3 is a cross-sectional view illustrating a comparison between sizes of the semiconductor package of FIG. 1 and a semiconductor package of a comparative example.

Referring to FIGS. 1 to 3, a semiconductor package 1000 of the present embodiment may include a package substrate 1100, an interposer 1200, a semiconductor device 1300, an underfill 1400, and a sealing material 1500.

The package substrate 1100 may be disposed under the interposer 1200, and may support the interposer 1200 and the semiconductor device 1300. The package substrate 1100 may include, for example, a ceramic substrate, a printed circuit board (PCB), an organic substrate, or an interposer substrate. In some embodiments, the package substrate 1100 may include an active substrate such as a silicon substrate. In the semiconductor package 1000 of the present embodiment, the package substrate 1100 may include a PCB. However, the package substrate 1100 is not limited to a PCB.

The package substrate 1100 may include a substrate body layer 1101 and a substrate pad 1120. The substrate body layer 1101 may constitute a body of the package substrate 1100 and may include multiple wiring layers therein. For example, when the package substrate 1100 is a PCB, the substrate body layer 1101 may include a core layer and a wiring layer.

The core layer may include, for example, a glass fiber and a resin such as FR4. Also, the core layer may include a bismaleimide-triazine (BT) resin, a poly carbonate (PC) resin, a build-up film such as an Ajinomoto build-up film (ABF), or another laminate resin. In some embodiments, the core layer may be omitted.

The wiring layer may be divided into an upper wiring layer and a lower wiring layer based on the core layer. Each of the upper wiring layer and the lower wiring layer may include wirings in a multi-layer structure. The number of layers of wirings of the upper wiring layer and the number of layers of wirings of the lower wiring layer may be the same or different from each other. In the semiconductor package 1000 of the present embodiment, the wiring layer of the package substrate 1100 may include wirings in an 8 to 20-layer structure. However, the number of layers of wirings of the wiring layer is not limited to the above numerical range.

The wiring layer may include wirings in a multi-layer structure, an interlayer insulating layer that insulates the wirings from each other, and a vertical via that connects the wirings to each other. The wiring and the vertical via may include, for example, copper (Cu). However, materials of the wiring and the vertical via are not limited to Cu. The interlayer insulating layer may include, for example, prepreg (PPG). However, a material of the interlayer insulating layer is not limited to PPG.

Although not shown, a protective layer may be disposed on a bottom surface and a top surface of the substrate body layer 1101. The protective layer may protect the substrate body layer 1101 and the wiring layer from external physical and chemical damage. The protective layer may include, for example, a solder resist (SR). However, a material of the protective layer is not limited to an SR. For example, the protective layer may include a passivation layer such as an oxide film or a nitride film, according to a type or a function of the substrate.

The substrate pad 1120 may be disposed on the bottom surface of the substrate body layer 1101. The substrate pad 1120 may be connected to wirings of the wiring layer. The substrate pad 1120 may be exposed from the protective layer disposed on the bottom surface of the substrate body layer 1101. An external connection terminal 1150 may be disposed on a bottom surface of the substrate pad 1120.

Although not shown, an upper substrate pad may be disposed on the top surface of the substrate body layer 1101. The upper substrate pad may be connected to wirings of the wiring layer and may be exposed from the protective layer disposed on the top surface of the substrate body layer 1101. A first connection terminal 1250 may be disposed on the upper substrate pad. For example, the upper substrate pad may be electrically connected to the interposer 1200 through the first connection terminal 1250.

The external connection terminal 1150 may be disposed on the substrate pad 1120 on a bottom surface of the package substrate 1100. The semiconductor package 1000 may be stacked on an external system substrate or a main board through the external connection terminal 1150. The external connection terminal 1150 may be connected to wirings of the wiring layer through the substrate pad 1120.

The external connection terminal 1150 may include a solder. The solder may include tin (Sn), indium (In), bismuth (Bi), antimony (Sb), copper (Cu), silver (Ag), zinc (Zn), and/or an alloy thereof. For example, the solder may include Sn, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, or Sn—Bi—Zn. In some embodiments, the solder may be referred to as a bump, a solder bump, or the like.

The interposer 1200 may mediate signal transmission between the package substrate 1100 and the semiconductor device 1300. For example, the interposer 1200 may mediate transmission of a signal or power between the package substrate 1100 and the semiconductor package 1300. In other words, the interposer 1200 may be mounted on the package substrate 1100 and may connect the semiconductor device 1300 to the package substrate 1100.

The interposer 1200 may include a body layer 1201, a wiring layer 1210, a through-electrode 1220, an interposer pad 1230, and a protective layer 1240. The body layer 1201 may include, for example, silicon (Si). Accordingly, the interposer 1200 may be an Si-interposer. However, the interposer 1200 is not limited to an Si-interposer.

The wiring layer 1210 may be disposed on the body layer 1201, and may include an interlayer insulating layer 1212 and wirings 1214. The wirings 1214 may be connected to the interposer pad 1230 on a top surface of the interposer 1200 at an upper portion of the wiring layer 1210, and may be connected to the through-electrode 1220 at a lower portion of the wiring layer 1210. Accordingly, the semiconductor device 1300 may be connected to the through-electrode 1220 of the interposer 1200 through a second connection terminal 1350 and the wirings 1214 of the wiring layer 1210.

The through-electrode 1220 may extend through the body layer 1201. When the body layer 1201 includes Si, the through-electrode 1220 may correspond to a through-silicon via (TSV). The through-electrode 1220 may extend inside the wiring layer 1210, and may be connected to the wirings 1214 of the wiring layer 1210. Also, the through-electrode 1220 may be connected to the first connection terminal 1250 through the interposer pad 1230 on a bottom surface of the interposer 1200.

The through-electrode 1220 may have a pillar shape, and may include a barrier film on an outer surface and a buried conductive layer therein. The barrier film may include at least one material selected from among Ti, TiN, Ta, TaN, Ru, Co, Mn, WN, Ni, and NiB. The buried conductive layer may include at least material selected from among Cu, a Cu alloy such as CuSn, CuMg, CuNi, CuZn, CuPd, CuAu, CuRe, or CuW, W, a W alloy, Ni, Ru, and Co. An insulating layer may be disposed between the through-electrode 1220 and the body layer 1201 or between the through-electrode 1220 and the wiring layer 1210. The insulating layer may include, for example, an oxide film, a nitride film, a carbide film, a polymer, or a combination thereof.

The interposer pad 1230 may include an interposer upper pad 1230u and an interposer lower pad 1230d. The interposer upper pad 1230u may be disposed on a top surface of the wiring layer 1210. The interposer upper pad 1230u may be connected to wirings of the wiring layer 1210, and may be connected to the through-electrode 1220 through the wirings of the wiring layer 1210. Also, the interposer upper pad 1230u may be connected to the semiconductor device 1300 through the second connection terminal 1350.

The interposer lower pad 1230d may be disposed on a bottom surface of the body layer 1201 and may be connected to the through-electrode 1220. The first connection terminal 1250 may be disposed on the interposer lower pad 1230d. The first connection terminal 1250 may be connected to the wirings of the wiring layer 1210 through the interposer lower pad 1230d and the through-electrode 1220.

The interposer pad 1230 may include at least one of, for example, aluminum (Al), copper (Cu), nickel (Ni), tungsten (W), platinum (Pt), and gold (Au). In the semiconductor package 1000 of the present embodiment, the interposer pad 1230 may include Cu. However, a material of the interposer pad 1230 is not limited to Cu.

The protective layer 1240 may be disposed on the bottom surface of the interposer 1200. The interposer lower pad 1230d may pass through at least a part of the protective layer 1240. For example, the interposer lower pad 1230d may pass through at least a part of the lower protective layer 1240 and may be connected to the through-electrode 1220. Although not shown, the protective layer 1240 may also be disposed on the top surface of the interposer 1200. The interposer upper pad 1230u may pass through at least a part of the protective layer on the top surface of the interposer 1200, and may be connected to the wirings of the wiring layer 1210.

The protective layer 1240 may include, for example, an oxide film, a nitride film, a carbide film, a polymer, or a combination thereof. However, a material of the protective layer 1240 is not limited thereto. The protective layer 1240 may have a single or multi-layer structure.

The first connection terminal 1250 may be disposed on the interposer pad 1230, for example, the interposer lower pad 1230d, on the bottom surface of the interposer 1200. The first connection terminal 1250 may be connected to the through-electrode 1220 through the interposer lower pad 1230d. The first connection terminal 1250 may include a solder. A material of the solder is the same as that described for the external connection terminal 1150.

In some embodiments, the first connection terminal 1250 may include a pillar and a solder, and the solder may be disposed on the pillar. The pillar may include, for example, nickel (Ni), copper (Cu), palladium (Pd), platinum (Pt), gold (Au), or a combination thereof. In some embodiments, the pillar may function as a pad and may include Cu. Accordingly, the pillar may be referred to as a bump pad, a Cu-pad, or a Cu-pillar. When the pillar functions as a pad, a separate pad may not be formed on the bottom surface of the interposer 1200.

In the semiconductor package 1000 of the present embodiment, the interposer 1200 may be a 2.5D interposer. However, the interposer 1200 is not limited to a 2.5D interposer. For example, the interposer 1200 may be a 2.3D interposer. For reference, the interposer may include a 2.5D interposer and a 2.3D interposer. Also, in some embodiments, an interposer structure, including an Si-bridge, may be further sub-divided. Accordingly, a structure excluding a 2.5D interposer is also referred to as a 2.xD interposer.

The 2.5D interposer usually refers to an Si-interposer, and may include a TSV therein. The 2.3D interposer may refer to an organic or inorganic interposer. In the case of an organic interposer, polyimide (PI), benzocyclobutene (BCB), or polybenzoxazole (PBO) may be used as a body layer, and in the case of an inorganic interposer, ceramic or glass may be used as a body layer. When the 2.3D interposer includes a through-electrode, the through-electrode may be referred to as a through-dielectric via (TDV), or a through-glass via (TGV) according to a material of a body layer. In some embodiments, the 2.3D interposer may be referred to as a panel level package (PLP) interposer or a re-distribution layer (RDL) interposer.

The semiconductor device 1300 may be mounted on the interposer 1200 through the second connection terminal 1350. The semiconductor device 1300 may include a chip or package structure. In the semiconductor package 1000 of the present embodiment, the semiconductor device 1300 may have a chip structure. For example, the semiconductor device 1300 may include a logic chip. Accordingly, the semiconductor device 1300 may include a plurality of logic devices therein.

Examples of the logic devices may include an AND, a NAND, an OR, a NOR, an exclusive OR (XOR), exclusive NOR (XNOR), an inverter (INV), an adder (ADD), a delay (DLY), a filter (FIL), a multiplexer (MXT/MXIT), an OR/AND/INVERTER (OAI), an AND/OR (AO), an AND/OR/INVERTER (AOI), a D flip-flop, a reset flip-flop, a master-slave flip-flop, a latch, a counter, and buffer devices. The logic devices may perform various signal processing such as analog signal processing, analog-to-digital (A/D) conversion, and control.

According to a function of the semiconductor device 1300, the semiconductor device 1300 may be referred to as a central processing unit (CPU) chip, a micro-processor unit (MPU) chip, a graphics processing unit (GPU) chip, a neural processing unit (NPU) chip, a system-on-glass (SOG) chip, an application-specific integrated circuit (ASIC) chip, an application processor (AP) chip, or a control chip.

In the semiconductor package 1000 of the present embodiment, the semiconductor device 1300 may have a chip structure, but may have a system-on-chip (SoC) structure, or a chiplet structure. The SoC structure may be a structure in which multiple systems are integrated into one chip. Accordingly, the semiconductor device 1300 having the SoC structure may perform a computational function, data storage, analog and digital signal conversion, etc. within a single chip. The chiplet structure may be a structure in which a logic chip is divided into separate chips according to functions and the chips are connected to each other. The semiconductor device 1300 having the chiplet structure may overcome the performance limitations of a single chip.

The semiconductor device 1300 may include devices supporting communication. However, in some embodiments, devices for supporting communication may be separately provided as other chips, for example, modem chips, and may be combined with the semiconductor device 1300 and disposed on the interposer 1200.

The semiconductor device 1300 may include a chip body 1301, an active layer 1310, and a chip pad 1330. The chip body 1301 may constitute a body of the semiconductor device 1300 and may include Si. However, a material of the chip body 1301 is not limited to Si. For example, the chip body 1301 may include another semiconductor material such as germanium (Ge) or Si-Ge, or a group III-V compound such as GaP, GaAs, or GaSb.

The active layer 1310 may be disposed under the chip body 1301 and may include an integrated circuit layer and a wiring layer. The integrated circuit layer may include a plurality of integrated devices. The integrated devices may include, logic devices described above. The wiring layer may be disposed under the integrated circuit layer. The wiring layer may include an interlayer insulating layer and wirings. The wirings may be disposed in two or more layers, and wirings of different layers may be connected to each other through a vertical via.

The chip pad 1330 may be disposed on a bottom surface of the active layer 1310. The chip pad 1330 may be connected to the wirings of the wiring layer of the active layer 1310. Although not shown, a protective layer may be disposed on the bottom surface of the active layer 1310, and the chip pad 1330 may pass through the protective layer and may be connected to the wirings of the wiring layer. The second connection terminal 1350 may be disposed on a bottom surface of the chip pad 1330.

In the semiconductor device 1300 of the semiconductor package 1000 of the present embodiment, a bottom surface may be a front side that is an active surface and a top surface may be a back side that is an inactive surface. In other words, a bottom side of the active layer 1310 may correspond to the front side of the semiconductor device 1300, and a top side of the chip body 1301 may correspond to the back side of the semiconductor device 1300.

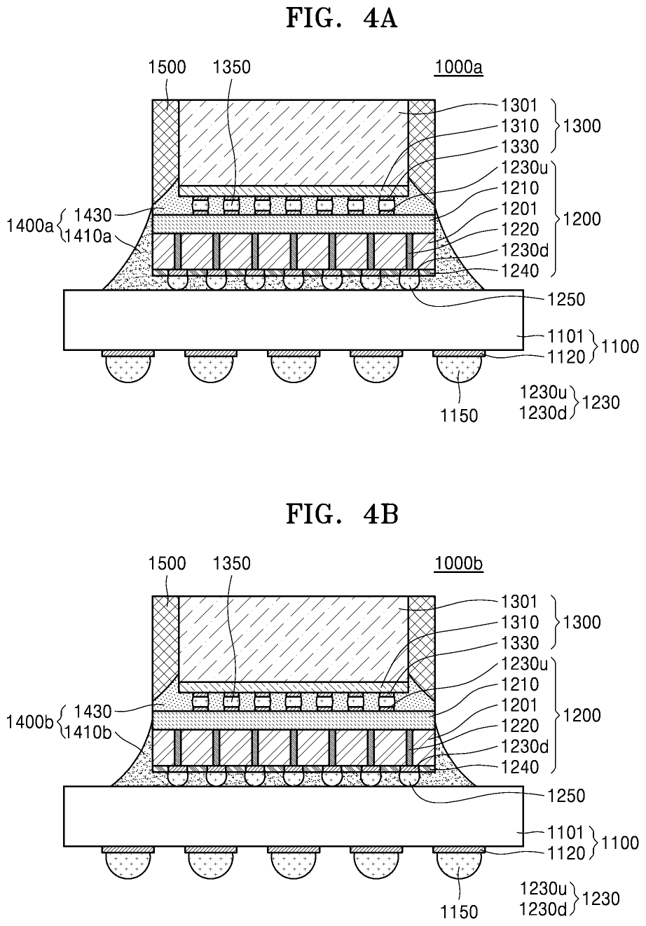

The underfill 1400 may include a first underfill 1410 and a second underfill 1430. The first underfill 1410 may be disposed between the package substrate 1100 and the interposer 1200. In detail, the first underfill 1410 may fill between the package substrate 1100 and the interposer 1200 and between the first connection terminals 1250. Also, the first underfill 1410 may cover a side surface of the interposer 1200. Also, as shown in FIG. 1, the first underfill 1410 may extend upward from a side surface of the interposer 1200 to cover a side surface of the second underfill 1430 and a part of a side surface of the sealing material 1500. However, a side surface structure of the first underfill 1410 is not limited thereto. Various side surface structures of the first underfill 1410 will be described in more detail with reference to FIGS. 4A and 4B.

The second underfill 1430 may be disposed between the interposer 1200 and the semiconductor device 1300. In detail, the second underfill 1430 may fill between the interposer 1200 and the semiconductor device 1300 and between the second connection terminals 1350. Also, the second underfill 1430 may cover a part of a side surface of the semiconductor device 1300. As shown in FIG. 2A, a side surface S of the second underfill 1430 may include an inclined side surface Ss and a vertical side surface Sv. Also, the vertical side surface Sv of the second underfill 1430 may be exposed from a side surface of the sealing material 1500 and may be covered by the first underfill 1410. In other words, the vertical side surface Sv of the second underfill 1430 may be adhered by directly contacting the first underfill 1410. Also, the vertical side surface Sv of the second underfill 1430 may be substantially coplanar with a side surface of the interposer 1200 and a side surface of the sealing material 1500. In one or more aspects, the term “being substantially coplanar with” may indicate that elements are coplanar with each other or may indicate that elements are not exactly coplanar with each other but within an industry-accepted tolerance, caused by a process error or a measurement error recognizable by one of ordinary skill in the art.

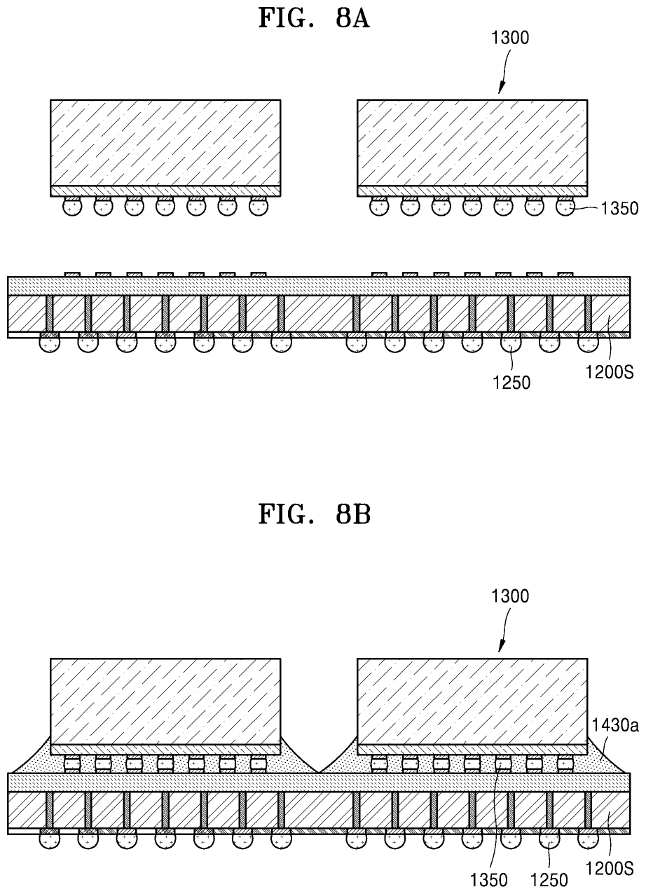

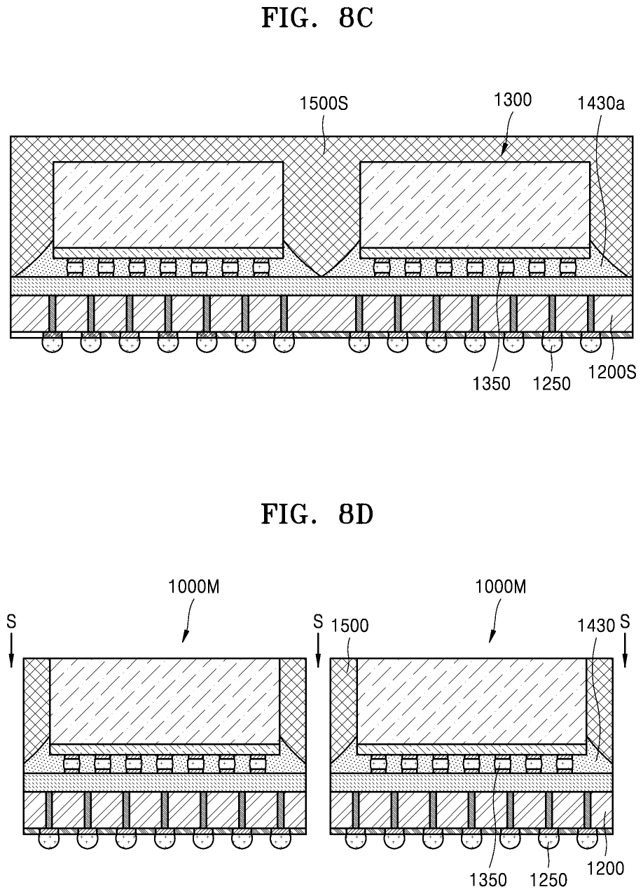

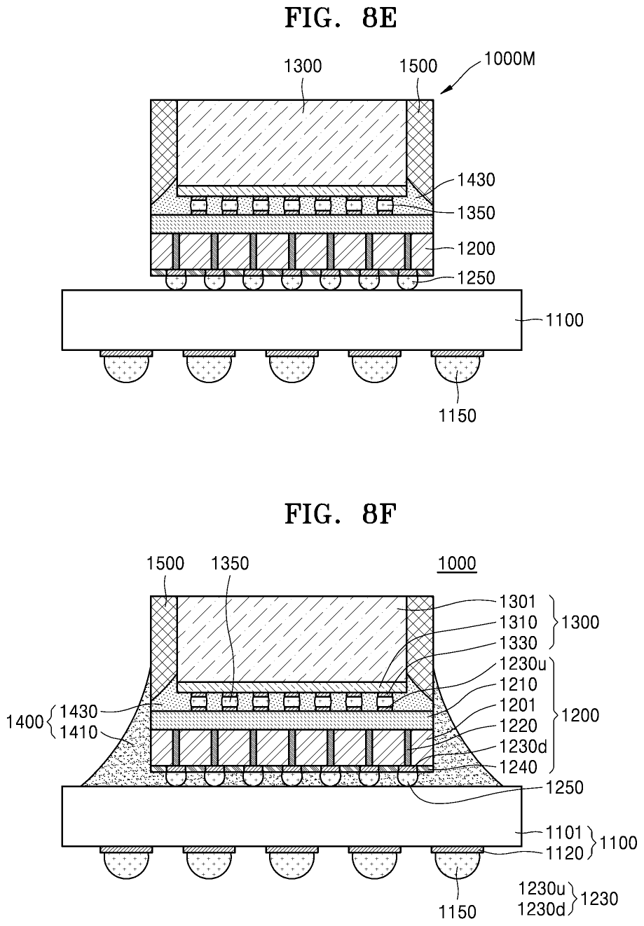

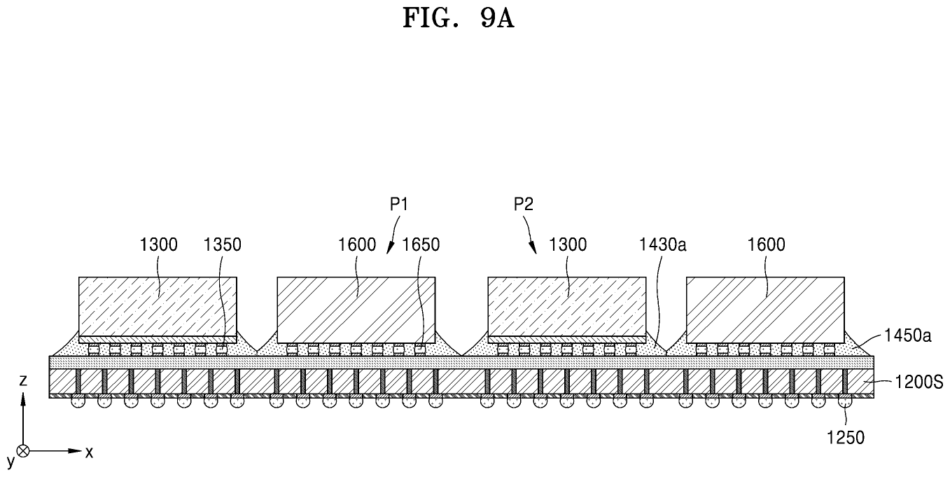

Meanwhile, when the shape of a top surface of the interposer 1200 has a rectangular shape, the vertical side surface Sv of the second underfill 1430 can be exposed from the side surface of the sealing material 1500 on at least one side of the rectangular shape. This may be due to a process of manufacturing an intermediate package 1000M (see FIG. 8D) including the semiconductor device 1300, the first underfill 1410, and the sealing material 1500. The process of manufacturing the intermediate package 1000M will be described in more detail when a method of manufacturing a semiconductor package is described with reference to FIGS. 8A to 8F.

In the semiconductor package 1000 of the present embodiment, the first underfill 1410 and the second underfill 1430 may include substantially the same material or different materials. In one or more aspects, the term “substantially the same material” may indicate that elements have the same material or may indicate that elements have almost the same material but within an industry-accepted tolerance in material composition, caused by a process error or a measurement error recognizable by one of ordinary skill in the art. Even when the first underfill 1410 and the second underfill 1430 include different materials, the first underfill 1410 and the second underfill 1430 may include materials having similar coefficients of thermal expansion (CTE). For example, each of the first underfill 1410 and the second underfill 1430 may have a CTE lower than that of the sealing material 1500.

In the semiconductor package 1000 of the present embodiment, because the vertical side surface Sv of the second underfill 1430 is exposed and the first underfill 1410 covers the vertical side surface Sv of the second underfill 1430, sizes of the package substrate 1100 and the interposer 1200 may be reduced, and thus, an overall size of the semiconductor package 1000 may be reduced. In detail, in FIG. 3, in a semiconductor package COM of a comparative example, a second underfill UF2 may be completely covered by a sealing material EMC, and a first underfill UF1 may cover only a part of a side surface of the sealing material EMC. That is, the second underfill UF2 and the first underfill UF1 may not contact each other. On the other hand, in the semiconductor package 1000 of the present embodiment, a vertical side surface of the second underfill 1430 may be exposed from a side surface of the sealing material 1500, and the first underfill 1410 may cover the vertical side surface of the second underfill 1430.

This structure of the semiconductor package 1000 of the present embodiment may be implemented by reducing a thickness of the sealing material 1500 on a side surface of the semiconductor device 1300. For example, a side surface thickness of the sealing material 1500 of the semiconductor package 1000 of the present embodiment may be less than a side surface thickness of the sealing material EMC of the semiconductor package COM of the comparative example by a first thickness D1, and thus, a width of the interposer 1200 may be reduced by the first thickness D1*2. Also, as a side surface thickness of the sealing material 1500 is reduced, a size of the package substrate 1100 may also be reduced. For example, a width of the package substrate 1100 of the semiconductor package 1000 of the present embodiment may be less than a width of a package substrate Sub of the semiconductor package COM of the comparative example by a second thickness D2*2. As a result, an overall size of the semiconductor package 1000 may be reduced by the reduced width of the package substrate 1100.

In the semiconductor package 1000 of the present embodiment, because the vertical side surface Sv of the second underfill 1430 is exposed from a side surface of the sealing material 1500, as marked by an arrow in FIG. 2A, the dehumidification effect of the second underfill 1430 may be increased. In other words, when the entire side surface S of the second underfill 1430 is covered by the sealing material 1500, the dehumidification effect may be suppressed due to the sealing material 1500. Also, as shown in FIG. 2B, even after the vertical side surface Sv of the second underfill 1430 is covered by the first underfill 1410, because the first underfill 1410 has a hardness or density that is substantially the same as the second underfill 1430, or if not the same, is lower than the sealing material 1500, the dehumidification effect may be increased compared to a structure covered by the sealing material 1500.

In the semiconductor package 1000 of the present embodiment, because the vertical side surface Sv of the second underfill 1430 is adhered to the first underfill 1410, thermal stress of the semiconductor package 1000 may be reduced and an adhesive force may be increased. In detail, in general, CTEs of the sealing material 1500 and the underfill 1400 may be different from each other. Accordingly, like in the structure of the semiconductor package COM of the comparative example, when the sealing material EMC covers the second underfill UF2 and the first underfill UF1 covers a side surface of the sealing material EMC, large thermal stress may occur due to a CTE difference between the sealing material EMC and the first and second underfills UF1 and UF2. The thermal stress may weaken an adhesive force between the sealing material EMC and the first and second underfills UF1 and UF2, and may also cause warpage of the semiconductor package COM.

However, in the semiconductor package 1000 of the present embodiment, as shown in a quadrangular portion B marked by a dashed dotted line in FIG. 2B, because the vertical side surface Sv of the second underfill 1430 having a similar CTE is directly adhered to the first underfill 1410, thermal stress may be reduced. Accordingly, warpage of the first semiconductor package 1000 may be suppressed. Also, because the first underfill 1410 and the second underfill 1430 formed of materials having similar CTEs are directly adhered to each other, an adhesive force between the first underfill 1410 and the second underfill 1430 may be increased.

For reference, in FIG. 3, IP may denote an interposer, and CH may denote a semiconductor device. Also, S1 and S2 may denote a first connection terminal and a second connection terminal, and So may denote an external connection terminal. In general, a chip-type package structure in which the semiconductor device CH is mounted on the interposer IP and sealed by the sealing material EMC may be referred to as a molded interposer (MIP) chip or a chip package. The semiconductor package COM of the comparative example having the chip package structure may be mounted on the package substrate Sub through the first connection terminal S1.

The sealing material 1500 may cover and seal the semiconductor device 1300 on the interposer 1200. As shown in FIG. 1, the sealing material 1500 may not cover a top surface of the semiconductor device 1300. For example, a top surface of the sealing material 1500 may be coplanar with the top surface of the semiconductor device 1300. However, in some embodiments, the top surface of the semiconductor device 1300 may be covered by the sealing material 1500.

The sealing material 1500 may cover a side surface of the semiconductor device 1300, and a part of a side surface of the second underfill 1430, that is, the inclined side surface Ss. However, as described above, the sealing material 1500 may not cover the vertical side surface Sv of the second underfill 1430. Accordingly, the vertical side surface Sv of the second underfill 1430 may be exposed from a side surface of the sealing material 1500.

The sealing material 1500 may include an insulating material, for example, a thermosetting resin such as an epoxy resin, a thermoplastic resin such as polyimide, or a resin including a reinforcing material such as an inorganic filler. For example, the sealing material 1500 may include ABF, FR-4, or BT resin. Also, the sealing material 1500 may include a molding material such as an epoxy mold compound (EMC) or a photosensitive material such as photo imageable encapsulant (PIE). However, a material of the sealing material 1500 is not limited to the above materials.

In some embodiments, the underfill 1400 may be replaced with an adhesive layer or an adhesive film. The adhesive layer or the adhesive film may include, for example, a non-conductive film (NCF). The NCF may be used as an adhesive layer when a semiconductor chip is adhered by using a thermal compression bonding (TCB) method, in a semiconductor chip stacking process. However, a material of the adhesive layer or the adhesive film is not limited to an NCF. Even when the underfill 1400 is replaced with an adhesive layer or an adhesive film, a side surface of the adhesive layer or the adhesive film corresponding to the second underfill 1430 may be exposed from a side surface of the sealing material 1500, and may be directly adhered to a side surface of an adhesive layer or an adhesive film corresponding to the first underfill 1410.

In the semiconductor package 1000 of the present embodiment, the vertical side surface Sv of the second underfill 1430 may be exposed from a side surface of the sealing material 1500, and the first underfill 1410 may be directly adhered to the vertical side surface Sv of the second underfill 1430. Accordingly, sizes of the package substrate 1100 and the interposer 1200 may be reduced, and an overall size of the semiconductor package 1000 may be reduced. Also, thermal stress of the semiconductor package 1000 may be reduced, and an adhesive force between the first underfill 1410 and the second underfill 1430 may be increased. Furthermore, the dehumidification effect of the second underfill 1430 may be increased.

FIGS. 4A and 4B are cross-sectional views illustrating a semiconductor package, according to embodiments. The same description as that made with reference to FIGS. 1 to 3 will be briefly provided or omitted.

Referring to FIG. 4A, a semiconductor package 1000a of the present embodiment may be different from the semiconductor package 1000 of FIG. 1 in a structure of an underfill 1400a. In detail, the semiconductor package 1000a of the present embodiment may include the package substrate 1100, the interposer 1200, the semiconductor device 1300, the underfill 1400a, and the sealing material 1500. The package substrate 1100, the interposer 1200, the semiconductor device 1300, and the sealing material 1500 are the same as those of the semiconductor package 1000 described with reference to FIG. 1.

The underfill 1400a may include a first underfill 1410a and the second underfill 1430. The first underfill 1410a may be disposed between the package 1100 and the interposer 1200 and may cover the first connection terminal 1250. Also, the first underfill 1410a may cover a side surface of the interposer 1200, and may cover a part of a side surface of the second underfill 1430. In detail, the first underfill 1410a may cover at least a part of a vertical side surface of the second underfill 1430. However, as shown in FIG. 4A, the first underfill 1410a may not cover a side surface of the sealing material 1500.

A structure of the second underfill 1430 is the same as that of the second underfill 1430 of the semiconductor package 1000 described with reference to FIG. 1. Also, materials of the first underfill 1410a and the second underfill 1430 are also the same as those of the first underfill 1410 and the second underfill 1430 of the semiconductor package 1000 described with reference to FIG. 1.

Referring to FIG. 4B, a semiconductor package 1000b of the present embodiment may be different from the semiconductor package 1000 of FIG. 1 in a structure of an underfill 1400b. In detail, the semiconductor package 1000b of the present embodiment may include the package substrate 1100, the interposer 1200, the semiconductor device 1300, the underfill 1400b, and the sealing material 1500. The package substrate 1100, the interposer 1200, the semiconductor device 1300, and the sealing material 1500 are the same as those of the semiconductor package 1000 described with reference to FIG. 1.

The underfill 1400b may include a first underfill 1410b and the second underfill 1430. The first underfill 1410b may be disposed between the package substrate 1100 and the interposer 1200 and may cover the first connection terminal 1250. Also, the first underfill 1410b may cover at least a part of a side surface of the interposer 1200. As shown in FIG. 4B, the first underfill 1410b may not cover a vertical side surface of the second underfill 1430. Also, the first underfill 1410b may not cover a side surface of the sealing material 1500.

A structure of the second underfill 1430 is the same as that of the second underfill 1430 of the semiconductor package 1000 described with reference to FIG. 1. Also, materials of the first underfill 1410b and the second underfill 1430 are the same as those of the first underfill 1410 and the second underfill 1430 of the semiconductor package 1000 described with reference to FIG. 1.

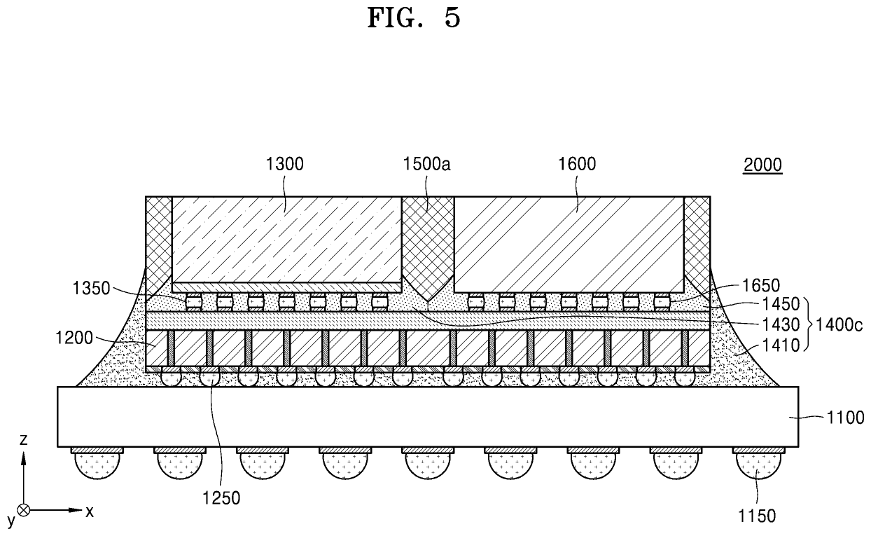

FIG. 5 is a cross-sectional view illustrating a semiconductor package, according to an embodiment. The same description as that made with reference to FIGS. 1 to 4B will be briefly provided or omitted.

Referring to FIG. 5, a semiconductor package 2000 of the present embodiment may be different from the semiconductor package 1000 of FIG. 1 in that a second semiconductor device 1600 is further included. Also, as the second semiconductor device 1600 is further included, structures of an underfill 1400c and a sealing material 1500a may be different from those of the semiconductor package 1000 of FIG. 1.

In detail, the semiconductor package 2000 of the present embodiment may include the package substrate 1100, the interposer 1200, a first semiconductor device 1300, the underfill 1400c, the sealing material 1500a, and the second semiconductor device 1600. The package substrate 1100, the interposer 1200, and the first semiconductor device 1300 are the same as those of the semiconductor package 1000 described with reference to FIG. 1.

Although the first semiconductor device 1300 has a slightly changed name from the semiconductor device 1300 of the semiconductor package 1000 of FIG. 1 in order to distinguish the second semiconductor device 1600, the first semiconductor device 1300 may substantially correspond to the semiconductor device 1300 of the semiconductor package 1000 of FIG. 1. Accordingly, the first semiconductor device 1300 may be mounted on the interposer 1200 through the second connection terminal 1350. As shown in FIG. 5, the first semiconductor device 1300 may be disposed on a left portion of the interposer 1200 in an x direction. However, a position of the first semiconductor device 1300 is not limited thereto.

The second semiconductor device 1600 may be mounted on the interposer 1200 through a third connection terminal 1650. As shown in FIG. 5, the second semiconductor device 1600 may be disposed on a right portion of the interposer 1200 in the x direction to be adjacent to the first semiconductor device 1300. However, a position of the second semiconductor device 1600 is not limited thereto. For example, the first semiconductor device 1300 may be disposed on a right portion of the interposer 1200 in the x direction, and the second semiconductor device 1600 may be disposed on a left portion of the interposer 1200 in the x direction.

The second semiconductor device 1600 may include memory devices. The second semiconductor device 1600 may include a volatile memory device such as dynamic random-access memory (DRAM) or static random-access memory (SRAM), or a nonvolatile memory device such as flash memory, phase-change random-access memory (PRAM), magnetoresistive random-access memory (MRAM), ferroelectric random-access memory (FeRAM), or resistive random-access memory (RRAM).

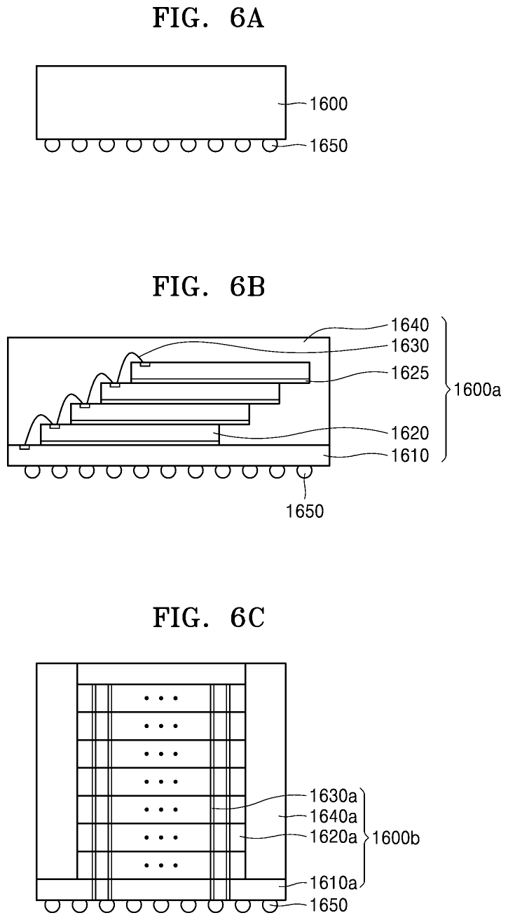

Also, the second semiconductor device 1600 may have a single chip structure or a package structure. In the semiconductor package 2000 of the present embodiment, the second semiconductor device 1600 may include, for example, a high bandwidth memory (HBM) package. However, the second semiconductor device 1600 is not limited to an HBM package. For example, the second semiconductor device 1600 may have a general package structure. In the general package structure, the second semiconductor device 1600 may include an upper package substrate, and a plurality of memory chips stacked on the upper package substrate. Also, the memory chips may be stacked on the upper package substrate through a bonding wire, or may be stacked on the upper package substrate through a bump and a TSV. The single chip structure or the package structure of the second semiconductor device 1600 will be described in more detail with reference to FIGS. 6A to 6C.

An underfill 1400c may include the first underfill 1410, the second underfill 1430, and a third underfill 1450. The first underfill 1410 and the second underfill 1430 are respectively the same as the first underfill 1410 and the second underfill 1430 of the semiconductor package 1000 described with reference to FIG. 1. However, as shown in FIG. 5, a side surface of a portion of the second underfill 1430 adjacent to the second semiconductor device 1600 may not be exposed from the sealing material 1500a. Also, the first underfill 1410 may cover a vertical side surface of the second underfill 1430 on a left side in the x direction, and may cover a vertical side surface of the third underfill 1450 on a right side.

The third underfill 1450 may be disposed between the interposer 1200 and the second semiconductor device 1600. In detail, the third underfill 1450 may fill between the interposer 1200 and the second semiconductor device 1600 and between the third connection terminals 1650. Also, the third underfill 1450 may cover a part of a side surface of the second semiconductor device 1600. A side surface of the third underfill 1450 may include an inclined side surface and a vertical side surface, like the second underfill 1430. Also, a right vertical side surface of the third underfill 1450 in the x direction may be exposed from a side surface of the sealing material 1500a and may be covered by the first underfill 1410. In other words, the right vertical side surface of the third underfill 1450 in the x direction may be adhered by directly contacting the first underfill 1410. Also, the right vertical side surface of the third underfill 1450 in the x direction may be substantially coplanar with a side surface of the interposer 1200 and a side surface of the sealing material 1500a.

As shown in FIG. 5, a left side surface of the third underfill 1450 in the x direction may contact a right side surface of the second underfill 1430 in the x direction. In some embodiments, the third underfill 1450 and the second underfill 1430 may not contact each other. In this structure, between the first semiconductor device 1300 and the second semiconductor device 1600, the sealing material 1500a may cover a top surface of the interposer 1200 and an entire side surface of each of the third underfill 1450 and the second underfill 1430.

The third underfill 1450 may include substantially the same material as that of the second underfill 1430. Accordingly, in a structure in which the third underfill 1450 contacts the second underfill 1430, a boundary portion between the third underfill 1450 and the second underfill 1430 may not be distinguished. In some embodiments, the third underfill 1450 may include a different material from the second underfill 1430, and in this case, in a structure in which the third underfill 1450 contacts the second underfill 1430, a boundary portion between the third underfill 1450 and the second underfill 1430 may be distinguished. However, even when the third underfill 1450 has a different material from the second underfill 1430, physical properties such as CTE may be similar to each other.

The sealing material 1500a may cover and seal the first semiconductor device 1300 and the second semiconductor device 1600 together on the interposer 1200. Also, as shown in FIG. 5, the sealing material 1500a may not cover top surfaces of the first semiconductor device 1300 and the second semiconductor device 1600. For example, a top surface of the sealing material 1500a may be coplanar with the top surfaces of the first semiconductor device 1300 and the second semiconductor device 1600. However, in some embodiments, the top surface of at least one of the first semiconductor device 1300 and the second semiconductor device 1600 may be covered by the sealing material 1500a.

As described above, a left vertical side surface Sv of the second underfill 1430 in the x direction may be exposed from a side surface of the sealing material 1500a. Also, a right vertical side surface of the third underfill 1450 in the x direction may be exposed from a side surface of the sealing material 1500a. Also, the sealing material 1500a may be disposed between the first semiconductor device 1300 and the second semiconductor device 1600 in the x direction. When a distance between the first semiconductor device 1300 and the second semiconductor device 1600 in the x direction is narrow, as shown in FIG. 5, the second underfill 1430 and the third underfill 1450 may contact each other, and the sealing material 1500a may cover a side surface of each of the second underfill 1430 and the third underfill 1450 and may be spaced apart from a top surface of the interposer 1200. Also, when a distance between the first semiconductor device 1300 and the second semiconductor device 1600 in the x direction is wide, the second underfill 1430 and the third underfill 1450 may be spaced apart from each other, and the sealing material 1500a between the first semiconductor device 1300 and the second semiconductor device 1600 may cover a top surface of the interposer 1200 and a side surface of each of the second underfill 1430 and the third underfill 1450. A material of the sealing material 1500a is the same as that of the sealing material 1500 of the semiconductor package 1000 described with reference to FIG. 1.

FIGS. 6A to 6C are detailed cross-sectional views illustrating a structure of a second semiconductor device in the semiconductor package of FIG. 5. The following will be described with reference to FIG. 5 together, and the same description as that made with reference to FIGS. 1 to 5 will be briefly provided or omitted.

Referring to FIG. 6A, the second semiconductor device 1600 may include one memory chip. The memory chip may include a volatile memory device such as DRAM or SRAM, or a nonvolatile memory device such as flash memory. In the semiconductor package 2000 of the present embodiment, the second semiconductor device 1600 may include, for example, a DRAM chip. The second semiconductor device 1600 may be mounted on the interposer 1200 (see FIG. 5) with a flip-chip bonding structure using the third connection terminal 1650. The third connection terminal 1650 may include a pillar and a solder, or may include only a solder.

Referring to FIG. 5, the third underfill 1450 may be disposed between the interposer 1200 and the second semiconductor device 1600. The third underfill 1450 may fill between the interposer 1200 and the second semiconductor device 1600 and between the third connection terminals 1650. The third underfill 1450 may cover a part of a side surface of the second semiconductor device 1600. Although not shown in FIG. 6A, the second semiconductor device 1600 and the third underfill 1450 may be covered by the sealing material 1500a. Also, in a process of manufacturing the intermediate package 1000M, a part of a side surface, for example, a vertical side surface, of the third underfill 1450 may be exposed from the sealing material 1500a.

Referring to FIG. 6B, a second semiconductor device 1600a may include a semiconductor package having a wire bonding structure and mounted on the interposer 1200 (see FIG. 5) through the third connection terminal 1650. In detail, the second semiconductor device 1600a may include an upper package substrate 1610 and a plurality of memory chips 1620 stacked on the upper package substrate 1610. The memory chip 1620 may be mounted on the upper package substrate 1610 with a wire bonding structure using a wire 1630 and an adhesive layer 1625. The memory chip 1620 of the second semiconductor device 1600a may include a volatile memory device such as DRAM or SRAM or a nonvolatile memory device such as flash memory. In the semiconductor package 2000 of the present embodiment, the memory chip 1620 of the second semiconductor device 1600a may include, for example, a DRAM chip.

Although four memory chips 1620 are stacked on the upper package substrate 1610 in FIG. 6B, the number of memory chips 1620 is not limited to four. For example, three or less, or five or more memory chips 1620 may be stacked on the upper package substrate 1610. Also, the memory chips 1620 are not limited to a stepped structure, and may be stacked in a zigzag structure or a combination of a stepped structure and a zigzag structure on the upper package substrate 1610.

The second semiconductor device 1600a may include an inner sealing material 1640 that seals the memory chip 1620 and the wire 1630 on the upper package substrate 1610. Also, the third underfill 1450 (see FIG. 5) may be disposed between the interposer 1200 (see FIG. 5) and the second semiconductor device 1600a. The third underfill 1450 may fill between the interposer 1200 and the second semiconductor device 1600a and between the third connection terminals 1650. The third underfill 1450 may cover a part of a side surface of the second semiconductor device 1600a, for example, a side surface of the upper package substrate 1610. Although not shown in FIG. 6B, the second semiconductor device 1600a and the third underfill 1450 may be covered by the sealing material 1500a. Also, in a process of manufacturing the intermediate package 1000M, a part of a side surface, for example, a vertical side surface, of the third underfill 1450 may be exposed from the sealing material 1500a.

Referring to FIG. 6C, a second semiconductor device 1600b may include an HBM package mounted on the interposer 1200 (see FIG. 5) through the third connection terminal 1650. In detail, the second semiconductor device 1600b may include a base chip 1610a, a plurality of core chips 1620a stacked on the base chip 1610a, and an inner sealing material 1640a. Also, the base chip 1610a and the core chips 1620a may include a through-electrode 1630a therein. An uppermost core chip 1620a among the core chips 1620a may not include the through-electrode 1630a.

The base chip 1610a may include logic devices. Accordingly, the base chip 1610a may be a logic chip. The base chip 1610a may be disposed under the core chips 1620a, may integrate signals of the core chips 1620a and transmit the integrated signals to the outside, and may transmit an external signal and power to the core chips 1620a. Accordingly, the base chip 1610a may be referred to as a buffer chip or a control chip.

Each of the core chips 1620a may be a memory chip. For example, each of the core chips 1620a may be a DRAM chip. The core chip 1620a may be stacked on the base chip 1610a or the core chip 1620a thereunder through pad-to-pad bonding, hybrid copper bonding (HCB), bonding using a connection terminal, or bonding using an anisotropic conductive film (ACF). The HCB may refer to a combination of pad-to-pad bonding and insulator-to-insulator bonding. Because a pad is usually formed of Cu, pad-to-pad bonding is also referred to as Cu-to-Cu bonding. The ACF is an ACF that provides electrical conductivity only in one direction and may refer to a conductive film formed by mixing fine conductive particles with an adhesive resin.

Although eight core chips 1620a are stacked on the base chip 1610a in FIG. 6C, the number of core chips 1620a is not limited to eight. For example, seven or less, or nine or more core chips 1620a may be stacked on the base chip 1610a.

The second semiconductor device 1600b may include the inner sealing material 1640a that seals the core chips 1620a on the base chip 1610a. However, a top surface of an uppermost core chip 1620a among the core chips 1620a may not be covered by the sealing material 1640a. However, in some embodiments, the top surface of the uppermost core chip 1620a may be covered by the inner sealing material 1640a.

The third underfill 1450 (see FIG. 5) may be disposed between the interposer 1200 (see FIG. 5) and the second semiconductor device 1600b. The third underfill 1450 may fill between the interposer 1200 and the second semiconductor device 1600b and between the third connection terminals 1650. The third underfill 1450 may cover a part of a side surface of the second semiconductor device 1600b, for example, a side surface of the base chip 1610a. Although not shown in FIG. 6C, the second semiconductor device 1600b and the third underfill 1450 may be covered by the sealing material 1500a. Also, in a process of manufacturing the intermediate package 1000M, a part of one side surface, for example, a vertical side surface, of the third underfill 1450 may be exposed from the sealing material 1500a.

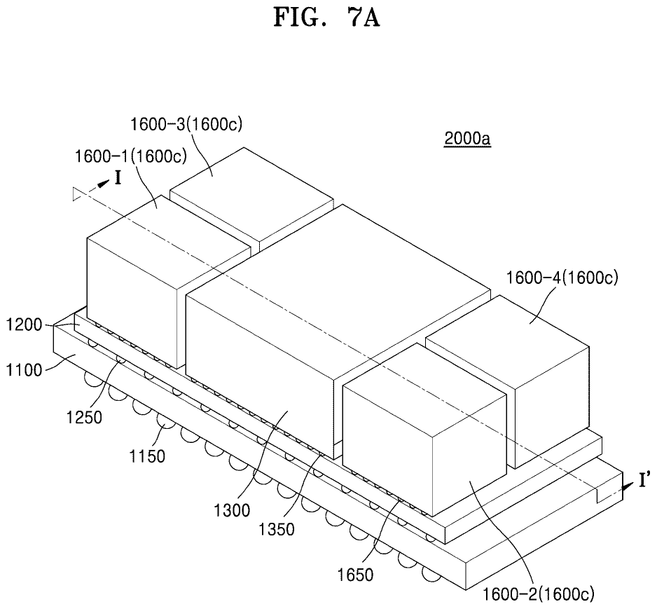

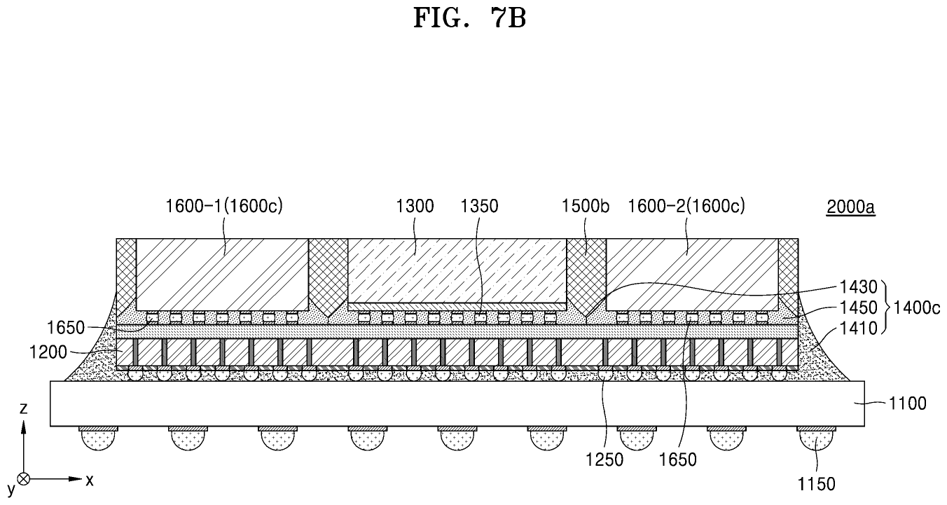

FIGS. 7A and 7B are a perspective view and a cross-sectional view illustrating a semiconductor package, according to an embodiment. An underfill and a sealing material are omitted and are not shown in FIG. 7A. The same description as that made with reference to FIGS. 1 to 6C will be briefly provided or omitted.

Referring to FIGS. 7A and 7B, a semiconductor package 2000a of the present embodiment may be different from the semiconductor package 2000 of FIG. 5 in that four second semiconductor devices 1600c are included. Also, as four second semiconductor devices 1600c are included, an arrangement structure of the first semiconductor device 1300 and the second semiconductor devices 1600c and structures of the underfill 1400c and a sealing material 1500b may be different from those of the semiconductor package 2000 of FIG. 5. In detail, the semiconductor package 2000a of the present embodiment may include the package substrate 1100, the interposer 1200, the first semiconductor device 1300, the underfill 1400c, the sealing material 1500b, and the second semiconductor device 1600c. The package substrate 1100, the interposer 1200, and the first semiconductor device 1300 are the same as those of the semiconductor package 2000 described with reference to FIG. 5. However, the first semiconductor device 1300 may be mounted on a central portion of the interposer 1200 in the x direction through the second connection terminal 1350.

The semiconductor package 2000a of the present embodiment may include four second semiconductor devices 1600c, as shown in FIG. 7A. For example, four second semiconductor devices 1600c may be disposed on the interposer 1200 through the third connection terminal 1650 so that two second semiconductor devices 1600c are disposed on one side of the first semiconductor device 1300 and two second semiconductor devices 1600c are disposed on the other side of the first semiconductor device 1300. In detail, a lower left second semiconductor device 1600-1 and an upper left second semiconductor device 1600-3 may be disposed on a left side of the first semiconductor device 1300, and a lower right second semiconductor device 1600-2 and an upper right second semiconductor device 1600-4 may be disposed on a right side of the first semiconductor device 1300. However, in the semiconductor package 2000a of the present embodiment, the number of second semiconductor devices 1600c is not limited to four. For example, two or three, or five or more second semiconductor devices 1600c may be disposed on the interposer 1200.

Each of the four second semiconductor devices 1600c may be correspond to, for example, the second semiconductor device 1600 of FIG. 5. Accordingly, the second semiconductor device 1600c may have a single chip structure or a package structure. In the semiconductor package 2000a of the present embodiment, the second semiconductor device 1600c may include an HBM package. However, the second semiconductor device 1600c is not limited to an HBM package. For example, the second semiconductor device 1600c may have a general package structure.

The underfill 1400c may include the first underfill 1410, the second underfill 1430, and the third underfill 1450. The first underfill 1410 to the third underfill 1450 are generally the same as the first underfill 1410 to the third underfill 1450 of the semiconductor package 2000 described with reference to FIG. 5. However, as the first semiconductor device 1300 is disposed on a central portion of the interposer 1200 in the x direction, as shown in FIG. 7B, the second underfill 1430 of the first semiconductor device 1300 may not be exposed from the sealing material 1500a.

In the third underfill 1450 of the second semiconductor device 1600c on a left side in the x direction, a left vertical side surface in the x direction may be exposed. Also, in the third underfill 1450 of the second semiconductor device 1600c on a right side in the x direction, a right vertical side surface in the x direction may be exposed. Due to this exposure structure of the third underfill 1450, the third underfill 1450 of the second semiconductor device 1600c on a left side in the x direction may have a left vertical side surface in the x direction covered by the first underfill 1410, and the third underfill 1450 of the second semiconductor device 1600c on a right side in the x direction may have a right vertical side surface in the x direction covered by the first underfill 1410. Also, the third underfill 1450 of the second semiconductor device 1600c on a left side in the x direction may have a left vertical side surface in the x direction substantially coplanar with a side surface of the interposer 1200 and a side surface of the sealing material 1500b. Also, the third underfill 1450 of the second semiconductor device 1600c on a right side in the x direction may have a right vertical side surface in the x direction substantially coplanar with a side surface of the interposer 1200 and a side surface of the sealing material 1500b.

As shown in FIG. 7B, the third underfill 1450 of the second semiconductor device 1600c on a left side in the x direction may have a right side surface in the x direction in contact with a left side surface of the second underfill 1430. Also, the third underfill 1450 of the second semiconductor device 1600c on a right side in the x direction may have a left side surface in the x direction in contact with a right side surface of the second underfill 1430. In some embodiments, the third underfill 1450 and the second underfill 1430 may not contact each other. In this structure, between the first semiconductor device 1300 and the second semiconductor device 1600c, the sealing material 1500b may cover a top surface of the interposer 1200 and a side surface of each of the third underfill 1450 and the second underfill 1430.

The sealing material 1500b may cover and seal the first semiconductor device 1300 and the second semiconductor device 1600c on the interposer 1200. Also, as shown in FIG. 7B, the sealing material 1500b may not cover top surfaces of the first semiconductor device 1300 and the second semiconductor device 1600c. For example, a top surface of the sealing material 1500b may be coplanar with the top surfaces of the first semiconductor device 1300 and the second semiconductor device 1600c. However, in some embodiments, the top surface of at least one of the first semiconductor device 1300 and the second semiconductor device 1600c may be covered by the sealing material 1500b.

As described above, in the third underfill 1450 of the second semiconductor device 1600c on a left side in the x direction, a left vertical side surface in the x direction may be exposed from a side surface of the sealing material 1500b. Also, in the third underfill 1450 of the second semiconductor device 1600c on a right side in the x direction, a right vertical side surface in the x direction may be exposed from a side surface of the sealing material 1500b. Also, the sealing material 1500b may be disposed between the first semiconductor device 1300 and the second semiconductor device 1600c in the x direction. When a distance between the first semiconductor device 1300 and the second semiconductor device 1600c in the x direction is narrow, as shown in FIG. 7B, the second underfill 1430 and the third underfill 1450 may contact each other, and the sealing material 1500b may cover a side surface of each of the second underfill 1430 and the third underfill 1450 and may be spaced apart from a top surface of the interposer 1200. Also, when a distance between the first semiconductor device 1300 and the second semiconductor device 1600c in the x direction is wide, the second underfill 1430 and the third underfill 1450 may be spaced apart from each other, and the sealing material 1500b between the first semiconductor device 1300 and the second semiconductor device 1600c may cover a top surface of the interposer 1200 and a side surface of each of the second underfill 1430 and the third underfill 1450. A material of the sealing material 1500b is the same as that of the sealing material 1500 of the semiconductor package 1000 described with reference to FIGS. 1 to 2B.

FIGS. 8A to 8F are cross-sectional views schematically illustrating processes of a method of manufacturing a semiconductor package, according to an embodiment. The following will be described with reference to FIG. 1 together, and the same description as that made with reference to FIGS. 1 to 7B will be briefly provided or omitted.

Referring to FIG. 8A, a method of manufacturing a semiconductor package of the present embodiment includes, first, mounting a plurality of semiconductor devices 1300 on an interposer substrate 1200S through the second connection terminal 1350. The interposer substrate 1200S is in a wafer state and may include a plurality of interposers 1200. Each of the semiconductor devices 1300 may be mounted at a corresponding position on the interposer substrate 1200S. Specific structures of the interposer 1200 and the semiconductor device 1300 are the same as those of the semiconductor package 1000 described with reference to FIG. 1.

For reference, the first connection terminal 1250 is disposed on a bottom surface of the interposer substrate 1200S, and the first connection terminal 1250 may be attached to the bottom surface of the interposer substrate 1200S before the semiconductor device 1300 is mounted as shown in FIG. 8A. However, in some embodiments, the first connection terminal 1250 may be attached to the bottom surface of the interposer substrate 1200S immediately before a sawing process of FIG. 8D. Also, in some embodiments, the first connection terminal 1250 may be attached to the bottom surface of the interposer substrate 1200S after the sawing process of FIG. 8D.

Referring to FIG. 8B, after the semiconductor devices 1300 are mounted, a second underfill 1430a is formed between the interposer substrate 1200S and each of the semiconductor devices 1300. The second underfill 1430a may fill between the interposer substrate 1200S and each of the semiconductor devices 1300 and between the second connection terminals 1350. Also, the second underfill 1430a may cover a part of a side surface of each of the semiconductor devices 1300. As shown in FIG. 8B, adjacent second underfills 1430a may contact each other. However, in some embodiments, adjacent second underfills 1430a may be spaced apart from each other.

The second underfill 1430a is the same as that of the semiconductor package 1000 described with reference to FIG. 1. However, a vertical side surface portion may not be formed on a side surface of the second underfill 1430a yet. In other words, as shown in FIG. 8B, a side surface of the second underfill 1430a may include only an inclined side surface.

Referring to FIG. 8C, after the second underfill 1430a is formed, a substrate sealing material 1500S that seals the semiconductor device 1300 is formed on the interposer substrate 1200S. The substrate sealing material 1500S may be formed at a wafer level. Accordingly, the substrate sealing material 1500S may cover all of the semiconductor devices 1300 on the interposer substrate 1200S. In detail, the substrate sealing material 1500S may cover a side surface and a top surface of each of the semiconductor devices 1300. Also, the substrate sealing material 1500S may cover a side surface of the second underfill 1430a. A material of the substrate sealing material 1500S is the same as that of the sealing material 1500 of the semiconductor package 1000 described with reference to FIG. 1.

Referring to FIG. 8D, after the substrate sealing material 1500S is formed, a back-grinding process of removing an upper portion of the substrate sealing material 1500S may be performed. A top surface of the semiconductor device 1300 may be exposed through the back-grinding process. Accordingly, the top surface of the semiconductor device 1300 may be substantially coplanar with a top surface of the substrate sealing material 1500S. In some embodiments, in the back-grinding process, a part of the substrate sealing material 1500S may be maintained on the top surface of the semiconductor device 1300, and in this case, the top surface of the semiconductor device 1300 may not be exposed.

Next, the interposer substrate 1200S and structures on the interposer substrate 1200S are individualized through a sawing process S. The intermediate package 1000M may be manufactured by an individualization process through the sawing process. The intermediate package 1000M may include the interposer 1200, the semiconductor device 1300, the second underfill 1430, and the sealing material 1500.

In the sawing process, the vertical side surface Sv may be formed on the side surface S of the second underfill 1430, and the vertical side surface Sv may be exposed from a side surface of the sealing material 1500. Also, due to the sawing process, the vertical side surface Sv of the second underfill 1430 may be substantially coplanar with a side surface of the interposer 1200 and a side surface of the sealing material 1500.

Referring to FIG. 8E, after the intermediate package 1000M is manufactured, the intermediate package 1000M is mounted on the package substrate 1100 through the first connection terminal 1250. The external connection terminal 1150 may be disposed on a bottom surface of the package substrate 1100. The external connection terminal 1150 may be attached before or after the intermediate package 1000M is mounted.

Referring to FIG. 8F, after the intermediate package 1000M is mounted, the first underfill 1410 is formed between the package substrate 1100 and the interposer 1200. The first underfill 1410 may fill between the package substrate 1100 and the interposer 1200 and between the first connection terminals 1250. Also, the first underfill 1410 may cover a side surface of the interposer 1200. Furthermore, the first underfill 1410 may cover a part of the side surface S of the second underfill 1430, for example, the vertical side surface Sv, and may cover a part of a side surface of the sealing material 1500. In some embodiments, the first underfill 1410 may cover only a part of the vertical side surface Sv of the second underfill 1430, and may not cover a side surface of the sealing material 1500. Also, in some embodiments, the first underfill 1410 may cover only a part of a side surface of the interposer 1200, and may not cover the vertical side surface Sv of the second underfill 1430. In this case, the vertical side surface Sv of the second underfill 1430 may be exposed from a side surface of the sealing material 1500 and may also be exposed from the first underfill 1410.

The semiconductor package 1000 may be completed through the formation of the first underfill 1410. The semiconductor package 1000 may correspond to, for example, the semiconductor package 1000 of FIG. 1. However, the inventive concept is not limited thereto, and according to a structure of the first underfill 1410, the semiconductor package 1000 may correspond to the semiconductor package 1000a or 1000b of FIG. 4A or 4B.

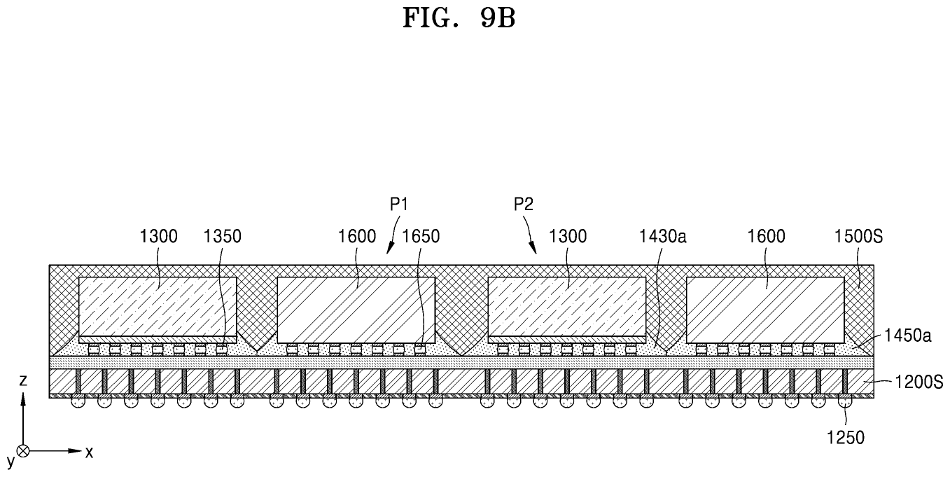

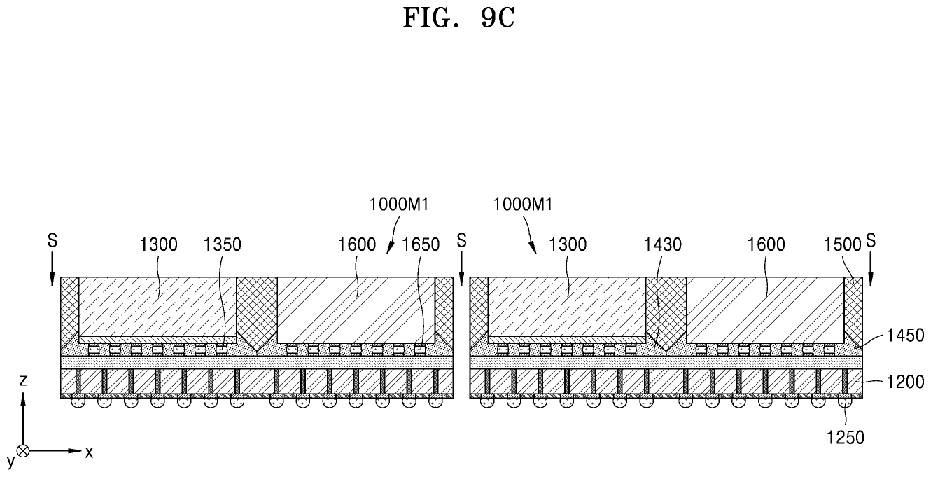

FIGS. 9A to 9C are cross-sectional views schematically illustrating processes of a method of manufacturing a semiconductor package, according to an embodiment. The following will be described with reference to FIG. 5 together, and the same description as that made with reference to FIGS. 8A to 8F will be briefly provided or omitted.

Referring to FIG. 9A, a method of manufacturing a semiconductor package of the present embodiment includes mounting a plurality of first semiconductor devices 1300 on the interposer substrate 1200S through the second connection terminal 1350, through the processes of FIGS. 8A and 8B. Also, a plurality of second semiconductor devices 1600 are mounted on the interposer substrate 1200S through the third connection terminal 1650. Each of the first semiconductor devices 1300 may correspond to the semiconductor device 1300 of FIG. 8A. Also, each of the second semiconductor devices 1600 may be disposed adjacent to the first semiconductor device 1300. In other words, one first semiconductor device 1300 and one second semiconductor device 1600 may be disposed adjacent to each other as a pair on the interposer substrate 1200S. As shown in FIG. 9A, an interval between the first semiconductor device 1300 and the second semiconductor device 1600 forming one pair may be narrower than an interval between pairs. In detail, an interval between the first semiconductor device 1300 and the second semiconductor device 1600 forming a first pair P1 may be narrower than an interval between the second semiconductor device 1600 of the first pair P1 and the first semiconductor device 1300 of a second pair P2.

The second underfill 1430a may be formed between the interposer substrate 1200S and each of the first semiconductor devices 1300. Also, the third underfill 1450a may be formed between the interposer substrate 1200S and each of the second semiconductor devices 1600. As described above, the second underfill 1430a and a third underfill 1450a may include substantially the same material. However, in some embodiments, the second underfill 1430a and the third underfill 1450a may include different materials. Also, due to an interval between the first semiconductor device 1300 and the second semiconductor device 1600, between the first semiconductor device 1300 and the second semiconductor device 1600 forming the first pair P1, the second underfill 1430a and the third underfill 1450a may contact each other with a large thickness. Also, between pairs, the second underfill 1430a and the third underfill 1450a may contact each other with a small thickness, or may be spaced apart from each other without contact.

Referring to FIG. 9B, after the second underfill 1430a and the third underfill 1450a are formed, the substrate sealing material 1500S that seals the first semiconductor device 1300 and the second semiconductor device 1600 is formed on the interposer substrate 1200S. The substrate sealing material 1500S may be formed at a wafer level. Accordingly, the substrate sealing material 1500S may cover all of the first semiconductor devices 1300 and the second semiconductor devices 1600 on the interposer substrate 1200S. In detail, the substrate sealing material 1500S may cover a side surface and a top surface of each of the first semiconductor devices 1300, and may cover a side surface and a top surface of each of the second semiconductor devices 1600. Also, the substrate sealing material 1500S may cover a side surface of the second underfill 1430a and a side surface of the third underfill 1450a. Between pairs, when the second underfill 1430a and the third underfill 1450a are spaced apart from each other without contact, the substrate sealing material 1500S may cover a top surface of the interposer 1200 between the pairs.

Referring to FIG. 9C, after the substrate sealing material 1500S is formed, a back-grinding process of removing an upper portion of the substrate sealing material 1500S may be performed. Through the back-grinding process, top surfaces of the first semiconductor device 1300 and the second semiconductor device 1600 may be exposed. Accordingly, the top surfaces of the first semiconductor device 1300 and the second semiconductor device 1600 may be substantially coplanar with a top surface of the substrate sealing material 1500S.

Next, the interposer substrate 1200S and structures on the interposer substrate 1200S are individualized through a sawing process S. Due to an individualization process through the sawing process, an intermediate package 1000M1 may be manufactured. The intermediate package 1000M1 may include the interposer 1200, the first semiconductor device 1300, the second underfill 1430, the third underfill 1450, the sealing material 1500, and the second semiconductor device 1600.

In the sawing process, a vertical side surface may be formed on a left side surface of the second underfill 1430 in the x direction, and the vertical side surface of the second underfill 1430 may be exposed from a side surface of the sealing material 1500. The vertical side surface of the second underfill 1430 may be substantially coplanar with a side surface of the interposer 1200 and a side surface of the sealing material 1500. Also, a vertical side surface may be formed on a right side surface of the third underfill 1450 in the x direction, and the vertical side surface of the third underfill 1450 may be exposed from a side surface of the sealing material 1500. The vertical side surface of the third underfill 1450 may be substantially coplanar with a side surface of the interposer 1200 and a side surface of the sealing material 1500.

Next, the semiconductor package 2000 may be completed by performing the processes of FIGS. 8E and 8F. The semiconductor package 2000 may correspond to, for example, the semiconductor package 2000 of FIG. 5.

According to another aspect of the inventive concept, a method of manufacturing a semiconductor package includes mounting a plurality of first semiconductor devices on an interposer substrate in a wafer state through first connection terminals, filling between the interposer substrate and the plurality of first semiconductor devices with a first underfill, forming a substrate sealing material on the interposer substrate to seal the plurality of first semiconductor devices, individualizing the interposer substrate and a structure on the interposer substrate through a sawing process to manufacture an intermediate package including an interposer, each first semiconductor device, and a sealing material, mounting the intermediate package on a package substrate through a second connection terminal, and filling between the package substrate and the intermediate package with a second underfill. The manufacturing of the intermediate package includes exposing a part of a side surface of the first underfill from a side surface of the sealing material.

In an embodiment, the manufacturing of the intermediate package may include forming a vertical side surface on the first underfill. The vertical side surface, the side surface of the sealing material, and a side surface of the interposer are substantially coplanar with each other.

In an embodiment, the filling with the first underfill may include covering at least a part of a side surface of each of the plurality of first semiconductor devices with the first underfill.

In an embodiment, the filling with the first underfill may include connecting between the first semiconductor devices adjacent to each other with the first underfill.

In an embodiment, the filling with the second underfill may include covering a side surface of the interposer and at least a part of a vertical side surface of the first underfill with the second underfill.

In an embodiment, the filling with the second underfill may include covering a side surface of the interposer, a vertical side surface of the first underfill, and at least a part of the side surface of the sealing material with the second underfill.

In an embodiment, a top surface of the interposer may have a rectangular shape. The manufacturing of the intermediate package includes forming a vertical side surface on the first underfill and exposing the vertical side surface from the side surface of the sealing material on at least one side of the rectangular shape.

In an embodiment, the mounting of the plurality of first semiconductor devices may include further mounting a plurality of second semiconductor devices on the interposer through third connection terminals to be adjacent to the plurality of first semiconductor devices. The filling with the first underfill includes filling between the interposer substrate and the plurality of second semiconductor devices with a third underfill.

In an embodiment, the manufacturing of the intermediate package may include forming a vertical side surface of the third underfill exposed from the side surface of the sealing material.

In an embodiment, each of the plurality of first semiconductor devices may include a logic chip, and each of the plurality of second semiconductor devices may include a high bandwidth memory (HBM) package including a plurality of dynamic random-access memory (DRAM) chips.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate;
an interposer disposed on the package substrate and connected to the package substrate through a first connection terminal and a first underfill;
a first semiconductor device disposed on the interposer and connected to the interposer through a second connection terminal and a second underfill; and
a sealing material disposed on the interposer and sealing a first semiconductor device,
wherein a part of a side surface of the second underfill is exposed from a side surface of the sealing material.

2. The semiconductor package of claim 1, wherein the side surface of the second underfill comprises an inclined side surface and a vertical side surface,
wherein the vertical side surface, the side surface of the sealing material, and a side surface of the interposer are substantially coplanar with each other.

3. The semiconductor package of claim 1, wherein the side surface of the second underfill comprises an inclined side surface and a vertical side surface, and
wherein the first underfill covers a side surface of the interposer and at least a part of the vertical side surface.

4. The semiconductor package of claim 1, wherein the side surface of the second underfill comprises an inclined side surface and a vertical side surface, and
wherein the first underfill covers a side surface of the interposer, the vertical side surface, and at least a part of the side surface of the sealing material.

5. The semiconductor package of claim 1, wherein a top surface of the interposer has a rectangular shape,
wherein the side surface of the second underfill comprises an inclined side surface and a vertical side surface, and
wherein the vertical side surface is exposed from the side surface of the sealing material on at least one side of the rectangular shape.

6. The semiconductor package of claim 1, further comprising at least one second semiconductor device disposed adjacent to the first semiconductor device on the interposer and connected to the interposer through a third connection terminal and a third underfill.

7. The semiconductor package of claim 6, wherein a part of a side surface of the third underfill is exposed from the side surface of the sealing material.

8. The semiconductor package of claim 6, wherein
the first semiconductor device comprises a logic chip, and
the at least one second semiconductor device comprises a memory chip.

9. The semiconductor package of claim 6, wherein the at least one second semiconductor device comprises a high bandwidth memory (HBM) package comprising a plurality of dynamic random-access memory (DRAM) chips.

10. The semiconductor package of claim 1, wherein the first underfill and the second underfill comprise substantially a same material.

11. A semiconductor package comprising:
a package substrate;
an interposer disposed on the package substrate and connected to the package substrate through a first connection terminal;
a first semiconductor device disposed on the interposer and connected to the interposer through a second connection terminal;
a first underfill disposed between the package substrate and the interposer and covering the first connection terminal;
a second underfill disposed between the interposer and the first semiconductor device and covering the second connection terminal; and
a sealing material disposed on the interposer and sealing a first semiconductor device,
wherein the second underfill covers at least a part of a side surface of the first semiconductor device, and a first side surface of the second underfill is exposed from a side surface of the sealing material, and
the first underfill covers a side surface of the interposer and at least a part of the first side surface of the second underfill.

12. The semiconductor package of claim 11, wherein the first side surface is a vertical side surface of the second underfill, and
wherein the first side surface, the side surface of the sealing material, and the side surface of the interposer are substantially coplanar with each other.

13. The semiconductor package of claim 11, wherein the first underfill covers the first side surface and at least a part of the side surface of the sealing material.

14. The semiconductor package of claim 11, wherein a top surface of the interposer has a rectangular shape, and
wherein the first side surface is exposed from the side surface of the sealing material on at least one side of the rectangular shape.

15. The semiconductor package of claim 11, wherein the interposer comprises:
an interposer substrate,
a wiring layer on the interposer substrate, and
a through-electrode passing through the interposer substrate to connect the wiring layer to the first connection terminal, and
wherein the second connection terminal is connected to the through-electrode through the wiring layer.

16. A semiconductor package comprising:
a package substrate;
an interposer disposed on the package substrate and connected to the package substrate through a first connection terminal and a first underfill;
a first semiconductor device disposed on the interposer and connected to the interposer through a second connection terminal and a second underfill;
a second semiconductor device disposed adjacent to the first semiconductor device on the interposer and connected to the interposer through a third connection terminal and a third underfill; and
a sealing material disposed on the interposer and sealing the first semiconductor device and the second semiconductor device,
wherein a first side surface of the second underfill is exposed from a side surface of the sealing material.

17. The semiconductor package of claim 16, wherein the first side surface is a vertical side surface of the second underfill,
wherein the first side surface, the side surface of the sealing material, and a side surface of the interposer are substantially coplanar with each other.

18. The semiconductor package of claim 16, wherein a second side surface of the third underfill is exposed from another side surface of the sealing material,
wherein the second side surface, the another side surface of the sealing material, and another side surface of the interposer are substantially coplanar with each other.

19. The semiconductor package of claim 16, wherein the first underfill covers the first side surface and at least a part of the side surface of the sealing material.

20. The semiconductor package of claim 16, wherein
the first semiconductor device comprises a logic chip, and
the second semiconductor device comprises a high bandwidth memory (HBM) package comprising a plurality of dynamic random-access memory (DRAM) chips.
